(19) United States
(12) Patent Application Publication
(10) Pub. No.: US 2016/0204218 A1
(43) Pub. Date: Jul. 14, 2016

(54) SEMICONDUCTOR STRUCTURE COMPRISING AN ALUMINUM GATE ELECTRODE PORTION AND METHOD FOR THE FORMATION THEREOF

(71) Applicant: GLOBALFOUNDRIES Inc., Grand Cayman (KY)

(72) Inventors: Carsten Grass, Dresden (DE); Robert Binder, Dresden (DE); Joachim Metzger, Butzbach (DE)

(21) Appl. No.: 14/722,295

(22) Filed: May 27, 2015

Related U.S. Application Data
(60) Provisional application No. 62/102,392, filed on Jan. 12, 2015.

(51) Int. Cl. H01L 29/49; H01L 29/78; H01L 29/66

(52) U.S. Cl. CPC H01L 29/4966; H01L 29/66477; H01L 29/78

(57) ABSTRACT

An illustrative method includes providing a semiconductor structure. The semiconductor structure includes an active region and an electrically insulating structure. The active region includes a source region, a channel region and a drain region. The electrically insulating structure includes a recess over the channel region. A work function adjustment layer is deposited over the semiconductor structure. A portion of the work function adjustment layer is deposited at a bottom surface of the recess. The work function adjustment layer includes at least one material other than titanium nitride. A titanium nitride pre-wetting layer is deposited over the work function adjustment layer. A titanium wetting layer is deposited directly on the titanium nitride pre-wetting layer. After the deposition of the titanium wetting layer, the recess is filled with aluminum.

### BACKGROUND OF THE INVENTION

1. Field of the Invention

Generally, the present disclosure relates to integrated circuits and methods for the manufacturing thereof, and, more particularly, to integrated circuits including field effect transistors having gate electrodes including aluminum.

2. Description of the Related Art

Integrated circuits typically include a large number of circuit elements which include field effect transistors and, optionally, other circuit elements, such as capacitors, diodes and resistors. The circuit elements in an integrated circuit may be electrically connected by means of electrically conductive metal lines formed in a dielectric material. The electrically conductive metal lines may be provided in a plurality of interconnect layers, and they may be connected to the circuit elements and to each other by means of contact holes and contact vias that are filled with metal.

Field effect transistors include an active region formed in a semiconductor material such as, for example, silicon. The active region includes a source region, a drain region and a channel region between the source region and the drain region, wherein a doping of the channel region is different from a doping of the source region and the drain region. Above the channel region, a gate electrode that is separated from the channel region by a gate insulation layer may be provided. For increasing the capacity between the gate electrode and the channel region, high-k materials having a greater dielectric constant than silicon dioxide may be used for forming the gate insulation layer.

Furthermore, gate electrodes including a metal may be employed. The gate electrodes can include a work function adjustment layer over the gate insulation layer. A material of the work function adjustment layer may be adapted such that a work function of the gate electrode and a work function of the active region match. For N-channel transistors and P-channel transistors, different work function adjustment layers may be employed.

For forming field effect transistors including a gate insulation layer including a high-k material and a metal gate electrode, replacement gate techniques may be employed. In replacement gate techniques, dummy gate structures are formed over the channel regions of the field effect transistors. Adjacent the dummy gate structures, sidewall spacer structures may be provided, and ion implantation processes may be performed in the presence of the dummy gate structures and the sidewall spacer structures for forming source and drain regions. Additionally, an interlayer dielectric material may be deposited over the semiconductor structure. Thereafter, a chemical mechanical polishing process may be performed for exposing the dummy gate structures. Then, the dummy gate structures of field effect transistors of a first type, for example the dummy gate structures of P-channel field effect transistors, may be removed, and materials of a gate insulation layer including a high-k material, a work function adjustment layer and a gate electrode metal may be deposited. Thereafter, a chemical mechanical polishing process may be performed, and the dummy gate structures of the field effect transistors of the other type, for example the N-channel field effect transistors, may be removed. Then, layers of materials of the gate insulation layer, the work function adjustment layer and the gate electrode metal of the N-channel transistors may be deposited, and a chemical mechanical polishing process may be performed.

In the chemical mechanical polishing processes that are performed after the deposition of the materials of the gate insulation layers, the work function adjustment layers and the gate electrode metal, portions of the deposited materials outside the recesses formed by the removal of the dummy gate structures are removed for forming replacement gates in the recess. Since, in each of the chemical mechanical polishing processes, a portion of the sidewall spacer structures adjacent the dummy gate structures and the interlayer dielectric is also removed, the dummy gate structures are typically provided with a greater height than the final height of the replacement gate structures. Therefore, in the formation of field effect transistors having a small length of the channel region and the gate electrode, the gate electrode metal is filled into recesses having a relatively high aspect ratio between a depth of the recess and an extension of the recess along a channel length direction from the source region to the drain region.

The filling of recesses having a relatively high aspect ratio with the metal of the gate electrode may have issues associated therewith, which may include a formation of voids, which can adversely affect the functionality of the integrated circuit. In particular, a formation of voids may occur in the formation of P-channel field effect transistors in which, typically, the replacement gate process is performed first so that the recesses wherein the gate metal of the P-channel transistors is deposited have a greater depth than the recesses wherein the gate metal of the N-channel transistors is deposited.

In view of the above-described situation, the present disclosure provides semiconductor structures and methods that may help to avoid or at least reduce the formation of voids in replacement gate processes.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method disclosed herein includes providing a semiconductor structure. The semiconductor structure includes an active region and an electrically insulating structure. The active region includes a source region, a channel region and a drain region. The electrically insulating structure includes a recess over the channel region. A work function adjustment layer is deposited over the semiconductor structure. A portion of the work function adjustment layer is deposited at a bottom surface of the recess. The work function adjustment layer includes at least one material other than titanium nitride. A titanium nitride pre-wetting layer is deposited over the work function adjustment layer. A titanium wetting layer is deposited directly on the titanium nitride pre-wetting layer. After the deposition of the titanium wetting layer, the recess is filled with aluminum.

Another illustrative method disclosed herein includes providing a semiconductor structure. The semiconductor structure includes an active region and an electrically insulating structure. The active region includes a source region, a channel region and a drain region. The electrically insulating structure includes a recess over the channel region. At least a work function adjustment layer is deposited over the semiconductor structure. A portion of the work function adjustment layer is deposited at a bottom surface of the recess. The recess is filled with aluminum. The filling of the recess with aluminum includes a deposition of an aluminum seed layer over the work function adjustment layer. The deposition of the aluminum seed layer includes performing a first physical vapor deposition process at a temperature of about 100° C. or less. The filling of the recess with aluminum further includes performing a second physical vapor deposition process at a temperature of about 350° C. or more, wherein the second physical vapor deposition process is performed after the deposition of the aluminum seed layer.

An illustrative semiconductor structure disclosed herein includes an active region. The active region includes a source region, a channel region and a drain region. A gate insulation layer is formed over the channel region. A work function adjustment layer is formed over the gate insulation layer. The work function adjustment layer includes at least one material other than titanium nitride. A titanium nitride layer is formed over the work function adjustment layer. A titanium layer is formed directly on the titanium nitride layer. An aluminum gate electrode portion is formed directly on the titanium layer.

### BRIEF DESCRIPTION OF THE DRAWINGS

The disclosure may be understood by reference to the following description taken in conjunction with the accompanying drawings, in which like reference numerals identify like elements, and in which:

FIGS. 1-4 show schematic cross-sectional views of a semiconductor structure according to an embodiment in stages of a manufacturing process according to an embodiment; and

FIG. 5 shows an enlarged view of a portion of the semiconductor structure shown in FIG. 2.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Techniques as disclosed herein may be employed in the formation of P-channel field effect transistors by means of a replacement gate process wherein a work function adjustment layer that includes a first sublayer of tantalum nitride, a second sublayer of titanium nitride and a third sublayer of tantalum nitride is provided and wherein a gate metal including aluminum is deposited over the work function adjustment layer. The sublayers of the work function adjustment layer may be deposited by means of atomic layer deposition. A final gate height may be about 40 nm, and a height of dummy gate electrodes that are employed in a replacement gate process for forming the final gate electrodes may be about 10-20 nm or higher. Thus, a depth of the recesses wherein the final gate electrodes are formed, and which are obtained by removing the dummy gate structures, may be in a range from about 50-60 nm, and a width thereof may be about 40 nm or less, in a range from about 20-40 nm and/or about 25 nm. After the deposition of the work function adjustment layer, the extension of the recesses in the channel length direction may be only about 15 nm or less, which can lead to a relatively high aspect ratio of the recesses at a stage of the manufacturing process wherein the gate electrode metal including aluminum is deposited.

Techniques as disclosed herein may enable a substantially void-free aluminum fill into relatively narrow trenches having a relatively narrow trench width of about 15 nm or less and an aspect ratio between the trench width and a depth of the trench of about 3:1 or higher and/or about 4:1 or higher. In particular, techniques as disclosed herein may enable an aluminum fill into recesses formed by a removal of dummy gate structures for gate critical dimensions of about 30 nm or less with a dummy gate height in a range from about 60-70 nm.

In embodiments disclosed herein, a titanium nitride pre-wetting layer may be formed over a work function adjustment layer including tantalum nitride. On the titanium nitride pre-wetting layer, a titanium wetting layer may be deposited. The titanium nitride pre-wetting layer can protect the titanium wetting layer from oxidation and an outgassing effect of the work function adjustment layer, in particular from the tantalum nitride. The titanium nitride pre-wetting layer may be deposited by means of an atomic layer deposition process with a good sidewall coverage. Then, the titanium wetting layer, which may have a thickness in a range from about 3-6 nm, may be deposited by means of a physical vapor deposition process.

Then, the aluminum of the gate electrode may be deposited. This may be done in two steps. First, an aluminum seed layer may be deposited at a temperature of less than about 100° C., for example, at about room temperature, in a physical vapor deposition process with a small biasing to sputter the aluminum already into the small trenches. Thereafter, an aluminum fill may take place. In doing so, an aluminum fill layer having a relatively high thickness of, for example, about 50 nm or more and/or about 100 nm or more may be deposited by means of a physical vapor deposition process that can have a relatively high deposition rate and may be performed at a temperature of about 300° C. or more, for example, at about 400° C. Thereafter, an aluminum reflow process may be performed for removing remaining metal voids and allowing the aluminum to flow into the gate trenches. The presence of the titanium nitride pre-wetting layer may improve a flow of aluminum during the reflow process, even if an insufficient sidewall coverage and/or a too large overhang of the titanium wetting layer should be obtained in the physical vapor deposition thereof compared to processes wherein a titanium wetting layer is deposited directly on a work function adjustment layer including tantalum nitride. Tantalum nitride can adversely affect the wetting of the aluminum, even at relatively high reflow temperatures. In some embodiments, the complete process sequence may be performed without vacuum break.

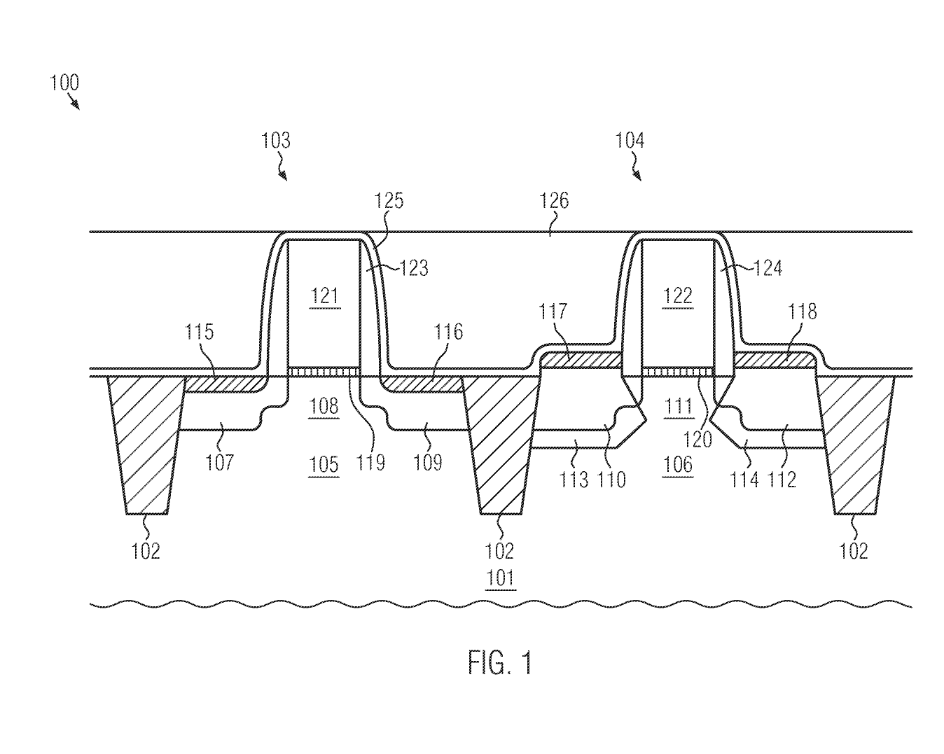

In the following, further embodiments will be described with reference to FIGS. 1-5. FIG. 1 shows a schematic cross-sectional view of a semiconductor structure 100 according to an embodiment in a stage of a manufacturing process according to an embodiment. The semiconductor structure 100 includes a semiconductor substrate 101. The substrate 101 may include a semiconductor wafer, for example, a bulk semiconductor wafer formed of a semiconductor material such as silicon or a semiconductor-on-insulator (SOI) wafer that includes a layer of a semiconductor material, for example silicon, that is provided over a layer of an electrically insulating material such as, for example, silicon dioxide. The layer of electrically insulating material may be provided on a support wafer, which may be a silicon wafer.

The semiconductor structure 100 further includes an N-channel transistor element 103 and a P-channel transistor element 104 which are formed at the substrate 101. A trench isolation structure 102 provides electrical insulation between the N-channel transistor element 103 and the P-channel transistor element 104 and between the transistor elements 103, 104 and other circuit elements of the semiconductor structure 100.

The N-channel transistor element 103 may include an active region 105 that is provided in the semiconductor material of the substrate 101. In the active region 105, a source region 107, a channel region 108 and a drain region 109 may be provided. The source region 107 and the drain region 109 of the N-channel transistor element 103 may be N-doped. The channel region 108, which is located between the source region 107 and the drain region 109, may be doped differently than the source region 107 and the drain region 109. For example, the channel region 108 may be P-doped or substantially undoped. In the source region 107 and the drain region 109, silicide regions 115, 116, respectively, may be provided.

Over the channel region 105, a dummy gate electrode 121 of the N-channel transistor element 103 may be provided. The dummy gate electrode 121 may be replaced with a final gate electrode of the N-channel transistor element 103 in later stages of the manufacturing process. Between the channel region 108 and the dummy gate electrode 121, a gate insulation layer 119 may be provided. In some embodiments, the gate insulation layer 119 may be a dummy gate insulation layer that will be removed in later stages of the manufacturing process together with the dummy gate electrode 121 and replaced by a final gate insulation layer of the N-channel transistor element 103. In other embodiments, the gate insulation layer 119 may be a final gate insulation layer of the N-channel transistor element 103, and only the dummy gate electrode 121 may be replaced by the final gate electrode of the N-channel transistor element 103. Adjacent the dummy gate electrode 121, a sidewall spacer structure 123 may be provided.

The P-channel transistor element 104 includes an active region 106. The active region 106 includes a source region 110, a channel region 111 and a drain region 112. The source region 110 and the drain region 112 of the P-channel transistor element 104 may be P-doped. The channel region 111 may be doped differently than the source region 110 and the drain region 112, for example, N-doped or substantially undoped.

In some embodiments, stress creating regions 113, 114 may be provided at the source region 110 and the drain region 112. In the stress creating regions 113, 114, a semiconductor material having a different crystal lattice constant than the semiconductor material of the substrate 101 may be provided for creating an elastic stress in the channel region 111 of the P-channel transistor element 104. The stress creating regions 113, 114 may include silicon germanium, which has a crystal lattice constant that is greater than the crystal lattice constant of substantially pure silicon for creating a compressive stress in the channel region 111. A compressive stress in the channel region 111 may improve the mobility of holes.

An interface between the stress creating regions 113, 114 and the channel region 111 may have a so-called sigma shape, wherein upper portions of the interfaces between the stress creating regions 113, 114 and the channel region 111 are inclined inwardly with respect to the channel region 111, and lower portions of the interfaces between the stress creating regions 113, 114 and the channel region 111 are inclined outwardly with respect to the channel region 111.

Additionally, the P-channel transistor element 104 may include a dummy gate electrode 122 that is provided above the channel region 111 and separated therefrom by a gate insulation layer 120. In later stages of the manufacturing process, the dummy gate electrode 122 may be removed and replaced by a final gate electrode of the P-channel transistor element 104. In some embodiments, the gate insulation layer 120 may be a dummy gate insulation layer that is replaced by a final gate insulation layer of the P-channel transistor element 104. In other embodiments, the gate insulation layer 120 may be a final gate insulation layer of the P-channel transistor element 104, and only the dummy gate electrode 122 may be replaced. Adjacent the dummy gate electrode 122, a sidewall spacer structure 124 may be provided.

In some embodiments, the stress creating regions 113, 114 may include a raised source region and a raised drain region, respectively, which are located above a level of the interface between the gate insulation layer 120 and the channel region 111, as shown in FIG. 1. In the raised source region 110, a silicide region 117 may be provided, and in the raised drain region 112, a silicide region 118 may be provided.

The semiconductor structure 100 may further include an etch stop layer 125 that is provided over the N-channel transistor element 103 and the P-channel transistor element 104. Additionally, an interlayer dielectric layer 126 may be provided. Over the dummy gate electrodes 121, 122, the etch stop layer 125 may be exposed at a surface of the semiconductor structure 100.

The etch stop layer 125 and the interlayer dielectric 126 may be formed of materials that may be etched selectively relative to each other. For example, in some embodiments, the etch stop layer 125 may include silicon nitride, and the interlayer dielectric 126 may include silicon dioxide.

The above-described features of the semiconductor structure 100 may be formed by means of known techniques for forming semiconductor structures. In particular, techniques of photolithography, etching, oxidation, deposition and/or chemical mechanical polishing may be performed for forming the trench isolation structure 102. For providing the gate insulation layers 119, 120 and the dummy gate electrodes 121, 122, layers of materials of the gate insulation layers 119, 120 and the dummy gate electrodes 121, 122 may be formed over the substrate 101 by means of known techniques of deposition and/or oxidation.

In embodiments wherein the gate insulation layers 119, 120 are dummy gate insulation layers, the gate insulation layers 119, 120 may include silicon dioxide, and they may be formed from a layer of silicon dioxide which may be formed by means of a thermal oxidation process. Chemical vapor deposition or plasma-enhanced chemical vapor deposition may also be employed. In embodiments wherein the gate insulation layers 119, 120 are final gate insulation layers of the N-channel transistor element 103 and the P-channel transistor element 104, the gate insulation layers 119, 120 may include a high-k dielectric material having a greater dielectric constant than silicon dioxide such as, for example, hafnium dioxide, zirconium dioxide and/or hafnium zirconium dioxide, and they may be formed from a layer of the high-k material that is deposited over the semiconductor structure 100 by means of a chemical vapor deposition process, a plasma-enhanced chemical vapor deposition process and/or an atomic layer deposition process. The dummy gate electrodes 121, 122 may include polysilicon, and they may be formed from a polysilicon layer that is deposited over the semiconductor structure 100 by means of a chemical vapor deposition process or a plasma-enhanced chemical vapor deposition process.

After the formation of the material layers from which the gate insulation layers 119, 120 and the dummy gate electrodes 121, 122 are formed, the layers may be patterned by means of processes of photolithography and etching for forming the gate insulation layers 119, 120 and the dummy gate electrodes 121, 122.

The sidewall spacer structures 123, 124 may be formed by means of known techniques for forming sidewall spacer structures which may include an isotropic deposition and an anisotropic etching of one or more layers of one or more sidewall spacer materials, such as silicon nitride and/or silicon dioxide.

The stress creating regions 113, 114 may be obtained by performing an etch process adapted to remove the semiconductor material of the substrate 101 and then performing a selective epitaxial growth process adapted for depositing the material of the stress creating regions 113, 114. For obtaining a sigma shape of the stress creating regions 113, 114, a crystallographically anisotropic etch process may be performed. In the crystallographically anisotropic etch process, an etch chemistry including tetramethylammoniumhydroxide (TMAH) may be used. During the etch process and the selective epitaxial growth process, the N-channel transistor element 103 may be covered by a mask so that stress creating regions 113, 114 are formed only in the P-channel transistor element 104.

The source regions 107, 110 and the drain regions 109, 112 may be formed by means of ion implantation processes, wherein an ion implantation may be performed both before the formation of the sidewall spacer structures 123, 124 and after the formation of the sidewall spacer structures 123, 124 for obtaining desired dopant profiles of the source regions 107, 110 and the drain regions 109, 112. Masks may be employed for differently doping the source and drain regions 107, 109 of the N-channel transistor element 103 and the source and drain regions 110, 112 of the P-channel transistor element 104.

The silicide regions 115, 116, 117, 118 may be formed by depositing a layer of a metal such as, for example, nickel over the semiconductor structure 100 and performing one or more annealing processes for inducing a chemical reaction between the metal and the semiconductor materials in the source regions 107, 110 and the drain regions 109, 112. Unreacted residues of the metal may be removed by means of an etch process.

For forming the etch stop layer 125 and the interlayer dielectric layer 126, known deposition techniques such as chemical vapor deposition and/or plasma-enhanced chemical vapor deposition may be employed. After the deposition of the material of the interlayer dielectric layer 126, a chemical mechanical polishing process may be performed for obtaining a planar surface of the semiconductor structure 100 and for exposing portions of the etch stop layer 125 over the dummy gate electrodes 121, 122.

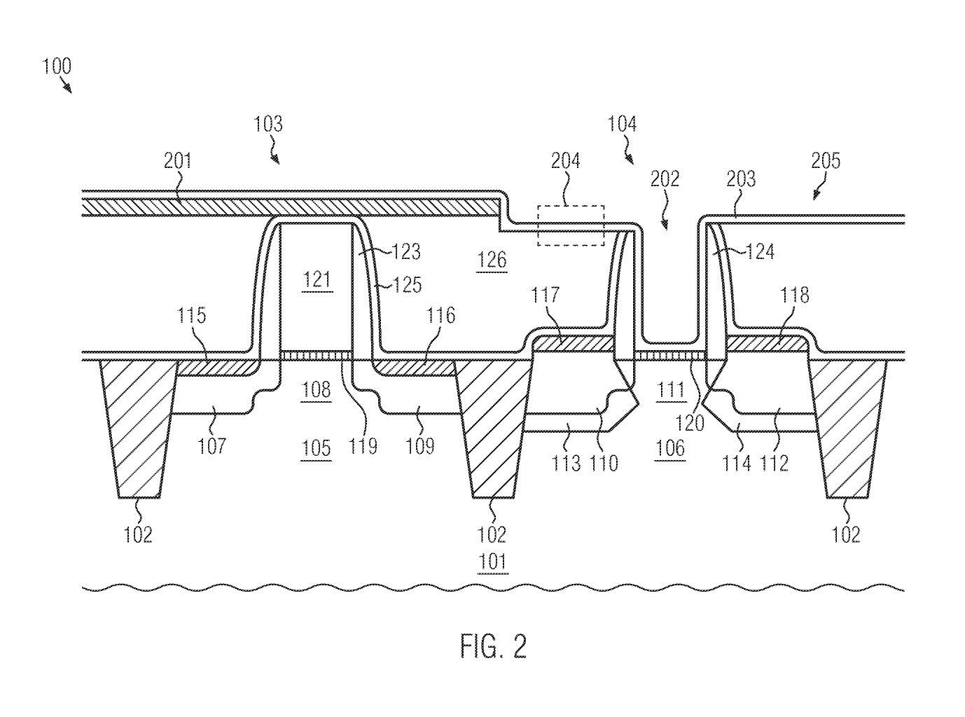

FIG. 2 shows a schematic cross-sectional view of the semiconductor structure 100 in a later stage of the manufacturing process. A replacement gate process for the P-channel transistor element 104 may be performed, as will be described in the following.

A hardmask 201 that covers the N-channel transistor element 103 but not the P-channel transistor element 104 may be formed over the semiconductor structure 100. For this purpose, a layer of a hardmask material such as, for example, silicon nitride may be deposited over the semiconductor structure 100, and it may be patterned by means of processes of photolithography and etching for removing portions of the layer of hardmask material over the P-channel transistor element 104.

Thereafter, one or more etch processes may be performed for removing the dummy gate electrode 122 of the P-channel transistor element 104 and the portion of the etch stop layer 125 over the dummy gate electrode 122.

In embodiments wherein the gate insulation layer 120 of the P-channel transistor element 104 is a final gate insulation layer of the P-channel transistor element 104, the gate insulation layer 120 is not removed in the one or more etch processes that are performed for removing the dummy gate electrode 122 and remains in the semiconductor structure 100, as shown in FIG. 2. In embodiments wherein the gate insulation layer 120 is a dummy gate insulation layer, the gate insulation layer 120 may also be removed in the one or more etch processes, and the final gate insulation layer of the P-channel transistor element 104 may be formed thereafter by depositing a layer of a high-k material from which the final gate insulation layer of the P-channel transistor element 104 is formed over the semiconductor structure 100. In the following, reference will be made to “gate insulation layer 120,” wherein it is to be understood that a replacement gate insulation layer may be present instead.

After the removal of the dummy gate electrode 122 of the P-channel transistor element 104, the semiconductor structure 100 includes a recess 202 at the location of the dummy gate electrode 122. The sidewall spacer structure 124, the etch stop layer 125 and the interlayer dielectric 126, which are formed of electrically insulating materials, form an electrically insulating structure 205 wherein the recess 202 is provided. Since the sidewall spacer structure 124, the etch stop layer 125 and the interlayer dielectric 126 may include different materials, the electrically insulating structure 205 may include portions that are formed of different electrically insulating materials. In particular, the electrically insulating structure 205 may include portions that are formed of silicon dioxide such as, for example, the interlayer dielectric 126, and portions that are formed of silicon nitride such as, for example, the etch stop layer 125 and portions of the sidewall spacer structure 124. Sidewalls of the recess 202 are provided by the sidewall spacer structure 124, and the gate insulation layer 120 is provided at a bottom surface of the recess 202.

Dimensions of the recess 202 may correspond to dimensions of the dummy gate electrode 122. In particular, a depth of the recess 202 may be approximately equal to a height of the dummy gate electrode 122, being an extension of the dummy gate electrode 122 in a thickness direction of the substrate 101 that is approximately perpendicular to an interface between the gate insulation layer 120 and the channel region 111 of the P-channel transistor element 104 (vertical in the view of FIGS. 1-4).

An extension of the recess 202 in a channel length direction of the P-channel transistor element 104 from the source region 110 to the drain region 112 of the P-channel transistor element 104 (horizontal in the view of FIGS. 1-4) may be approximately equal to an extension of the dummy gate electrode 122 in the channel length direction. Moreover, an extension of the recess 202 in a channel width direction of the P-channel transistor element 104 (perpendicular to the plane of drawing of FIGS. 1-4) may be approximately equal to an extension of the dummy gate electrode 122 in the channel width direction.

In some embodiments, after the removal of the dummy gate electrode 122, the depth of the recess 202 may be in a range from about 50-60 nm. The extension of the recess 202 in the channel length direction of the P-channel transistor element 104 may be less than about 40 nm. For example, it may be in a range from about 20-40 nm, for example about 20 nm, about 28 nm or about 32 nm.

The extension of the recess 202 in the channel width direction of the P-channel transistor element 104 may be in a range from about 100 nm to about 2 μm.

Since the extension of the recess 202 in the channel width direction of the P-channel transistor element 104 may be greater than the extension of the recess 202 in the channel length direction of the P-channel transistor element 104, the recess 202 may have a shape of an elongated trench, wherein the extension of the recess 202 in the channel length direction of the P-channel transistor element 104 corresponds to the width of the trench.

After the removal of the dummy gate electrode 122 and, in embodiments wherein the gate insulation layer 120 is a dummy gate insulation layer, after the formation of the final gate insulation layer of the P-channel transistor element 104, a work function adjustment layer 203 may be deposited over the semiconductor structure 100, wherein a portion of the work function adjustment layer 203 is deposited on the gate insulation layer of the P-channel transistor element 104 at the bottom of the recess 202.

The work function adjustment layer 203 may include a material other than titanium nitride, for example, tantalum nitride. In addition to the material other than titanium nitride, the work function adjustment layer 203 may include titanium nitride.

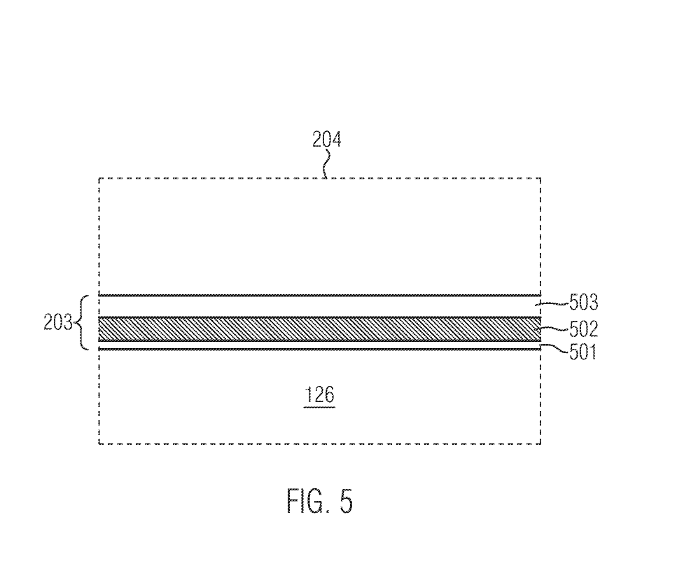

FIG. 5 shows an enlarged cross-sectional view of a portion 204 of the semiconductor structure 100 at the stage of the manufacturing process illustrated in FIG. 2. As shown in FIG. 5, the work function adjustment layer 203 may include a first sublayer 501 that is provided directly on a portion of the semiconductor structure 100 below the work function adjustment layer 203. In the portion 204 of the semiconductor structure 100, the first sublayer 501 of the work function adjustment layer 203 is provided directly on the interlayer dielectric 126. Portions of the first sublayer 501 over sidewalls of the recess 202 may be provided directly on the sidewall spacer structure 124, and portions of the first sublayer 501 of the work function adjustment layer 203 at the bottom surface of the recess 202 may be provided directly on the gate insulation layer 120 of the P-channel transistor element 104. Herein, a feature provided “directly on” another feature is to be understood as being in contact with the other feature in addition to being provided over the other feature.

The work function adjustment layer 203 may further include a second sublayer 502 that is provided over the first sublayer 501, for example directly on the first sublayer 501, and a third sublayer 503 that is provided over the second sublayer 502, for example directly on the second sublayer 502, so that the second sublayer 502 is arranged between the first sublayer 501 and the third sublayer 503.

The first sublayer 501 of the work function adjustment layer 203 may include tantalum nitride, and it may have a thickness in a range from about 1-2 nm. The second sublayer 502 of the work function adjustment layer 203 may include titanium nitride, and it may have a thickness in a range from about 3-5 nm. The third sublayer 503 of the work function adjustment layer 203 may include tantalum nitride, and it may have a thickness in a range from about 3-5 nm. A thickness of the second sublayer 502 may be approximately equal to a thickness of the third sublayer 503, and the first sublayer 501 may have a smaller thickness than the second sublayer 502 and the third sublayer 503.

For depositing the sublayers 501, 502, 503 of the work function adjustment layer 203, atomic layer deposition techniques may be employed.

In other embodiments, the work function adjustment layer 203 may have a different composition and/or a different number of sublayers.

The deposition of the work function adjustment layer 203 may reduce dimensions of the trench 202. In particular, a depth of the trench 202 may be reduced by a thickness of the portion of the work function adjustment layer 203 at the bottom of the recess 202 that is located on the gate insulation layer 120, and extensions of the recess 202 in the channel length direction and the channel width direction of the P-channel transistor element 104 may each be reduced by twice a thickness of portions of the work function adjustment layer 203 at the sidewall spacer structure 124, which provides sidewalls of the recess 202. Thus, an aspect ratio between the depth of the recess 202 and the extension of the recess 202 along the channel length direction of the P-channel transistor element 104 may be increased. In some embodiments, after the deposition of the work function adjustment layer 203, the aspect ratio between the depth of the recess 202 and the extension of the recess 202 along the channel length direction of the P-channel transistor element 104 may be about 3:1 or more and/or about 4:1 or more. In some embodiments, the extension of the recess 202 along the channel length direction of the P-channel transistor element 104 may be about 15 nm or less after the deposition of the work function adjustment layer 203.

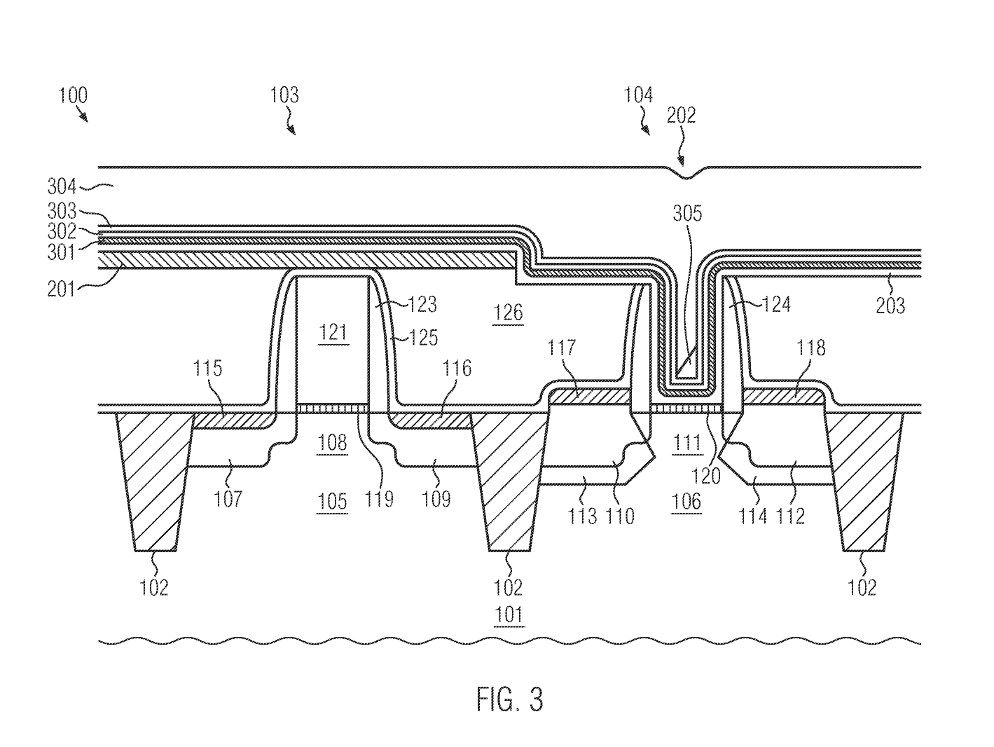

FIG. 3 shows a schematic cross-sectional view of the semiconductor structure 100 in a later stage of the manufacturing process. A titanium nitride pre-wetting layer 301 may be deposited over the work function adjustment layer 203. The titanium nitride pre-wetting layer 301 may be deposited directly on the third sublayer 503 of the work function adjustment layer 203. The titanium nitride pre-wetting layer 302 may have a thickness in a range from about 1-2 nm, and it may be formed by means of an atomic layer deposition process adapted for the deposition of titanium nitride. Forming the titanium nitride pre-wetting layer 301 by means of atomic layer deposition may provide a better coverage of the sidewalls of the recess 202 than a formation of the titanium nitride pre-wetting layer 301 by means of other deposition techniques, such as physical vapor deposition.

A titanium wetting layer 302 may be deposited directly on the titanium nitride pre-wetting layer 301. The titanium wetting layer 302 may include elementary titanium, i.e., titanium that is not provided in the form of a chemical compound, and it may be formed by means of a physical vapor deposition process, in particular by means of sputtering. A thickness of the titanium wetting layer 302 may be in a range from about 3-6 nm. The formation of the titanium wetting layer 302 may be performed by means of a deposition only process, wherein no intermediate etchback of the deposited titanium is performed.

The titanium nitride pre-wetting layer 301 can protect the titanium wetting layer 302 from adverse influences that might be caused by the tantalum nitride of the work function adjustment layer 203, in particular by the tantalum nitride of the third sublayer 503 of the work function adjustment layer 203. In particular, the titanium nitride pre-wetting layer 301 can help to reduce oxidation and outgassing effects of the work function adjustment layer 203.

After the formation of the titanium nitride pre-wetting layer 301 and the titanium wetting layer 302, the recess 202 may be filled with aluminum. The filling of the recess 202 with aluminum may include a deposition of an aluminum seed layer 303. The aluminum seed layer 303 may include elementary aluminum, i.e., aluminum that is not provided in the form of a chemical compound, and it may have a thickness in a range from about 3-40 nm. For depositing the aluminum seed layer 303, a physical vapor deposition process such as a sputtering process may be employed. The physical vapor deposition process may be performed at a temperature of about 100° C. or less, for example, at a temperature in a range from about −40° C. to about 100° C. In embodiments wherein the physical vapor deposition process for forming the aluminum seed layer 303 includes a sputtering process, a small negative bias voltage, for example a voltage in a range from about −35 V at about 100 W to about −500 V at about 1000 W, may be applied to the semiconductor structure 100 or a semiconductor structure holder on which the semiconductor structure 100 is provided. Due to the bias voltage, positive aluminum ions may be accelerated towards the semiconductor structure 100 so that a sputtering of the aluminum into the relatively narrow recess 202 is improved. Thus, a deposition of aluminum over portions of the titanium wetting layer 302 at the bottom of the recess 202 may be improved.

After the deposition of the aluminum seed layer 303, an aluminum fill layer 304 may be deposited over the semiconductor structure 100. The aluminum fill layer 304 may include substantially elementary aluminum, and it may be deposited by means of a physical vapor deposition process such as a sputtering process. The physical vapor deposition process employed for depositing the aluminum fill layer 304 may have a greater deposition rate than the physical vapor deposition process employed for depositing the aluminum seed layer 303 so that, during the deposition of the aluminum fill layer 304, a greater amount of aluminum is deposited over an area of the semiconductor structure 100 per unit time than during the deposition of the aluminum seed layer 303. The deposition of the aluminum fill layer 304 may be performed at a greater temperature than the deposition of the aluminum seed layer 303. In some embodiments, the physical vapor deposition process for depositing the aluminum fill layer 304 may be performed at a temperature of about 300° C. or more and/or at a temperature in a range from about 300° C. to about 500° C., for example, at a temperature of about 400° C.

Thicknesses of the aluminum seed layer 303 and the aluminum fill layer 304 may be adapted such that, after the deposition of the aluminum fill layer 304, the recess 202 is filled with aluminum at least to a level of an upper edge of the recess 202. In some embodiments, the thickness of the aluminum fill layer 304 may be about 50 nm or more, about 100 nm or more and/or in a range from about 50-250 nm.

Due to the relatively small extension of the recess 202 in the channel length direction of the P-channel transistor element 104 and the relatively high aspect ratio of the recess 202, in the filling of the recess 202 with aluminum, a formation of voids, as schematically denoted by reference numeral 305 in FIG. 3, may occur in some cases.

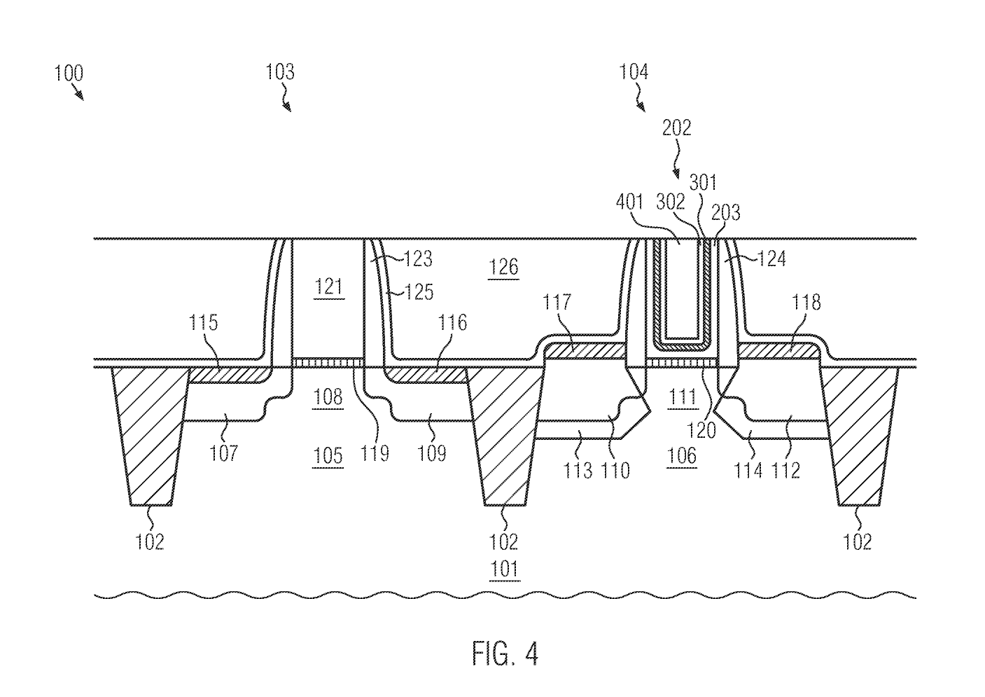

FIG. 4 shows a schematic cross-sectional view of the semiconductor structure 100 in a later stage of the manufacturing process. After the deposition of the aluminum fill layer 304, an aluminum reflow process may be performed. In the aluminum reflow process, the semiconductor structure 100 may be exposed to an elevated temperature for an amount of time so that aluminum from the aluminum fill layer 304 and/or the aluminum seed layer 303 can flow into the void 305 that may have been formed in the filling of the recess 302 with aluminum. Thus, the void 305 may be filled with aluminum, and a substantially void-free complete filling of the recess 202 with aluminum may be obtained.

In some embodiments, the aluminum reflow process may be performed at a temperature of about 350° C. or more, at a temperature in a range from about 350° C. to about 500° C. and/or at a temperature of about 400° C. The duration of the aluminum reflow process may be in a range from about 10 seconds (using temperatures in the upper range, for example, temperatures higher than 400° C.) to about 5 minutes (using temperatures in the lower range).

In some embodiments, the deposition of the titanium nitride pre-wetting layer 301, the deposition of the titanium wetting layer 302, the deposition of the aluminum seed layer 303, the deposition of the aluminum fill layer 304 and the aluminum reflow process may be performed without a vacuum break. For this purpose, a semiconductor manufacturing tool including process chambers for performing processes of an atomic layer deposition of titanium nitride, a physical vapor deposition of titanium and a physical vapor deposition of aluminum may be used. The semiconductor structure 100 may be transferred between process chambers without exposing the semiconductor structure 100 to ambient air. Thus, a contamination of the semiconductor structure 100 with oxygen and/or moisture may be substantially avoided or at least reduced. In further embodiments, the processes that are performed without a vacuum break may also include the deposition of the work function adjustment layer 203. In such embodiments, the process tool may also be provided with one or more process chambers that are adapted for performing processes of atomic layer deposition of tantalum nitride.

The present disclosure is not limited to embodiments wherein the recess 202 is filled with aluminum as described above. In other embodiments, the recess 202 may be filled with aluminum by means of a single physical vapor deposition process such as a sputtering process that is performed at a temperature in a range from about −40° C. to about 100° C. In the physical vapor deposition process, a layer including elementary aluminum and having a thickness that is sufficient to fill the recess 202 with aluminum at least to a level of its upper edge, for example a thickness in a range from about 3-200 nm, may be deposited over the semiconductor structure 100. Further features of the physical vapor deposition process may correspond to those of the physical vapor deposition process performed for depositing the aluminum seed layer 303 described above. Thereafter, a reflow process may be performed wherein the deposited aluminum layer is annealed. The reflow process may be performed at a temperature in a range from about 300-500° C., for example, at a temperature of about 400° C. Further features of the reflow process may correspond to those of the reflow process described above that is performed after the deposition of the aluminum fill layer 304.

After the aluminum reflow process, a chemical mechanical polishing process may be performed. In the chemical mechanical polishing process, portions of the work function adjustment layer 203, the titanium nitride pre-wetting layer 301, the titanium wetting layer 302, the aluminum seed layer 303 and the aluminum fill layer 304 outside the recess 202, as well as the mask 201 may be removed from the semiconductor structure 100.

Portions of the work function adjustment layer 203, the titanium nitride pre-wetting layer 301, the titanium wetting layer 302, the aluminum seed layer 303 and the aluminum fill layer 304 in the recess 202 may remain in the semiconductor structure 100 and provide an electrically conductive final gate electrode of the P-channel transistor element 104. The portions of the aluminum seed layer 303 and the aluminum fill layer 304 in the recess 202 may, after the aluminum reflow process and the chemical mechanical polishing process, form a substantially contiguous and void-free aluminum gate electrode portion 401.

Thereafter, a replacement gate process for the N-channel transistor element 103 may be performed, wherein the dummy gate electrode 121 of the N-channel transistor element 103 is replaced with a final gate electrode of the N-channel transistor element 103. Additionally, in embodiments wherein the gate insulation layer 119 of the N-channel transistor element 103 is a dummy gate insulation layer, the gate insulation layer 119 may be replaced with a final gate insulation layer of the N-channel transistor element 103.

The replacement gate process for the N-channel transistor element 103 may be performed in accordance with conventional replacement gate processes. In particular, the replacement gate process for the N-channel transistor element 103 may include a removal of the dummy gate electrode 121, a deposition of a work function adjustment layer and a gate electrode metal, wherein one or more materials of the work function adjustment layer of the N-channel transistor element 103 may be different from the materials of the work function adjustment layer 203 of the P-channel transistor element 104. The gate electrode metal for the N-channel transistor element 103 may include aluminum. A chemical mechanical polishing process may be performed for removing portions of the deposited material layers outside the recess that is formed by the removal of the dummy gate electrode 121 of the N-channel transistor element 103.

Thereafter, conventional backend processes may be performed for providing electrical contacts to the transistor elements 103, 104 and for forming one or more electrical interconnect layers over the semiconductor structure 100.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
providing a semiconductor structure, said semiconductor structure comprising an active region and an electrically insulating structure, said active region comprising a source region, a channel region and a drain region, said electrically insulating structure comprising a recess over said channel region;
depositing a work function adjustment layer over said semiconductor structure, a portion of said work function adjustment layer being deposited at a bottom surface of said recess, said work function adjustment layer comprising at least one material other than titanium nitride;
depositing a titanium nitride pre-wetting layer over said work function adjustment layer;
depositing a titanium wetting layer directly on said titanium nitride pre-wetting layer; and
after the deposition of said titanium wetting layer, filling said recess with aluminum.

2. The method of claim 1, wherein filling said recess with aluminum comprises depositing an aluminum seed layer directly on said titanium wetting layer, the deposition of said aluminum seed layer comprising performing a first physical vapor deposition process at a temperature of about 100° C. or less.

3. The method of claim 2, wherein filling said recess with aluminum further comprises, after the deposition of said aluminum seed layer, performing a second physical vapor deposition process at a temperature of about 300° C. or more.

4. The method of claim 3, further comprising, after performing said second physical vapor deposition process, performing an aluminum reflow process.

5. The method of claim 4, wherein said aluminum reflow process is performed at at least one of a temperature of about 350° C. or more and a temperature of about 400° C.

6. The method of claim 5, wherein, after the deposition of said work function adjustment layer, an aspect ratio between a depth of said recess and an extension of said recess along a channel length direction from said source region to said drain region is about 3:1 or more.

7. The method of claim 6, wherein said extension of said recess along said channel length direction is about 15 nm or less.

8. The method of claim 7, wherein the deposition of said work function adjustment layer comprises:
depositing a first sublayer of said work function adjustment layer, said first sublayer comprising tantalum nitride;
depositing a second sublayer of said work function adjustment layer, said second sublayer comprising titanium nitride; and
depositing a third sublayer of said work function adjustment layer, said third sublayer comprising tantalum nitride.

9. The method of claim 8, wherein said source region and said drain region are P-doped, said active region being an active region of a P-channel transistor.

10. The method of claim 9, wherein a replacement gate process for an N-channel transistor is performed after said aluminum reflow process.

11. A method, comprising:
providing a semiconductor structure, said semiconductor structure comprising an active region and an electrically insulating structure, said active region comprising a source region, a channel region and a drain region, said electrically insulating structure comprising a recess over said channel region;
depositing at least a work function adjustment layer over said semiconductor structure, a portion of said work function adjustment layer being deposited at a bottom surface of said recess; and
filling said recess with aluminum, the filling of said recess with aluminum comprising:
depositing an aluminum seed layer over said work function adjustment layer, the deposition of the aluminum seed layer comprising performing a first physical vapor deposition process at a temperature of about 100° C. or less; and
after the deposition of said aluminum seed layer, performing a second physical vapor deposition process at a temperature of about 300° C. or more.

12. The method of claim 11, further comprising, after performing said second physical vapor deposition process, performing an aluminum reflow process.

13. The method of claim 12, wherein said aluminum reflow process is performed at at least one of a temperature of about 350° C. or more and a temperature of about 400° C.

14. The method of claim 13, wherein, after the deposition of said work function adjustment layer, an aspect ratio between a depth of said recess and an extension of said recess along a channel length direction from said source region to said drain region is about 3:1 or more.

15. The method of claim 14, wherein said extension of said recess along said channel length direction is about 15 nm or less.

16. The method of claim 15, wherein said work function adjustment layer comprises at least one material other than titanium nitride.

17. The method of claim 16, further comprising, before the deposition of said aluminum seed layer, depositing a titanium nitride pre-wetting layer over said work function adjustment layer and depositing a titanium wetting layer directly on said titanium nitride pre-wetting layer.

18. The method of claim 17, wherein the deposition of said work function adjustment layer comprises:
depositing a first sublayer of said work function adjustment layer, said first sublayer comprising tantalum nitride;
depositing a second sublayer of said work function adjustment layer, said second sublayer comprising titanium nitride; and
depositing a third sublayer of said work function adjustment layer, said third sublayer comprising tantalum nitride.

19. The method of claim 18, wherein said source region and said drain region are P-doped, said active region being an active region of a P-channel transistor.

20. The method of claim 19, wherein a replacement gate process for an N-channel transistor is performed after said aluminum reflow process.

21. A semiconductor structure, comprising:
an active region, said active region comprising a source region, a channel region and a drain region;
a gate insulation layer formed over said channel region;
a work function adjustment layer formed over said gate insulation layer, said work function adjustment layer comprising at least one material other than titanium nitride;
a titanium nitride layer formed over said work function adjustment layer;
a titanium layer formed directly on said titanium nitride layer; and
an aluminum gate electrode portion formed directly on said titanium layer.

22. The semiconductor structure of claim 21, wherein said work function adjustment layer comprises:
a first sublayer comprising tantalum nitride;
a second sublayer comprising titanium nitride, said second sublayer being provided over said first sublayer; and
a third sublayer comprising tantalum nitride, said third sublayer being provided over said second sublayer.

23. The semiconductor structure of claim 22, wherein said source region and said drain region of said active region are P-doped, said active region being an active region of a P-channel transistor.
